(19) United States
(12) Patent Application Publication
(10) Pub. No.: US 2014/0340156 A1
(43) Pub. Date: Nov. 20, 2014

(54) AMPLIFIER

(71) Applicant: Kabushiki Kaisha Toshiba, Minato-ku (JP)

(72) Inventor: Kenta KURODA, Tokyo (JP)

(73) Assignee: Kabushiki Kaisha Toshiba, Minato-ku (JP)

(21) Appl. No.: 14/082,301

(22) Filed: Nov. 18, 2013

(30) Foreign Application Priority Data
May 16, 2013 (JP) 2013-104288

(51) Int. Cl. H03F 1/26

(52) U.S. Cl. CPC H03F 1/26
USPC 330/294

(57) ABSTRACT

An amplifier comprises a power amplifier for amplifying an unmodulated high-frequency input signal, a first branching device which is provided at an input terminal side of the power amplifier and extracts a signal, a second branching device which is provided at an output terminal side of the power amplifier and extracts a signal, a mixer for mixing a signal from the first branching device and a signal from the second branching device, a low-pass filter for removing a frequency band component of the input signal from an output signal of the mixer, a high-pass filter for removing a DC component from an output signal of the low-pass filter, and a wave detector for extracting a signal.

### CROSS-REFERENCE TO RELATED APPLICATIONS

This application is based upon and claims the benefit of priority from the prior the Japanese Patent Application No. 2013-104288, filed on May 16, 2013, and the entire contents of which are incorporated herein by reference.

### FIELD

The present invention relates to an amplifier.

### BACKGROUND

There has been conventionally used a high-frequency heating device using a microwave. The high-frequency heating device uses a high-power unmodulated signal.

However, a load connected to a microwave signal source may largely change in its impedance during heating or processing. When the microwave signal source is formed of an oscillator and a semiconductor amplifier, an abnormal oscillation may occur due to impedance mismatch between an amplification circuit and a load. When an abnormal oscillation occurs, a standing wave exceeding a design allowed range can occur, and an amplification device such as transistor configuring the amplifier can be broken.

Power and frequency signals against the radio law can be output due to an abnormal oscillation.

An abnormal oscillation of the amplifier needs to be monitored.

In terms of this, there is proposed a technique for extracting a microwave signal outside a desired frequency band by use of a filter and detecting an abnormal oscillation.

However, a matching circuit with a distribution constant is used in a semiconductor amplifier in many cases, and thus the matching circuit easily oscillates near the used frequency band, such as loop oscillation in a λ/4 combiner.

To the contrary, it is difficult to detect an abnormal oscillation occurring near the used frequency band in the technique using a filter.

### BRIEF DESCRIPTION OF THE DRAWINGS

FIG. 1 is a diagram illustrating a structure of an amplifier; and

FIG. 2 is a diagram illustrating a structure of a variable of the amplifier.

### DETAILED DESCRIPTION

An amplifier according to one embodiment will be described below in detail with reference to the drawing.

The amplifier according to the present embodiment comprises a power amplifier for amplifying an unmodulated high-frequency input signal, a first branching device which is provided at an input terminal side of the power amplifier and extracts a signal, a second branching device which is provided at an output terminal side of the power amplifier and extracts a signal, a mixer for mixing a signal from the first branching device and a signal from the second branching device, a low-pass filter for removing a frequency band component of the input signal from an output signal of the mixer, a high-pass filter for removing a DC component from an output signal of the low-pass filter, and a wave detector for extracting a signal.

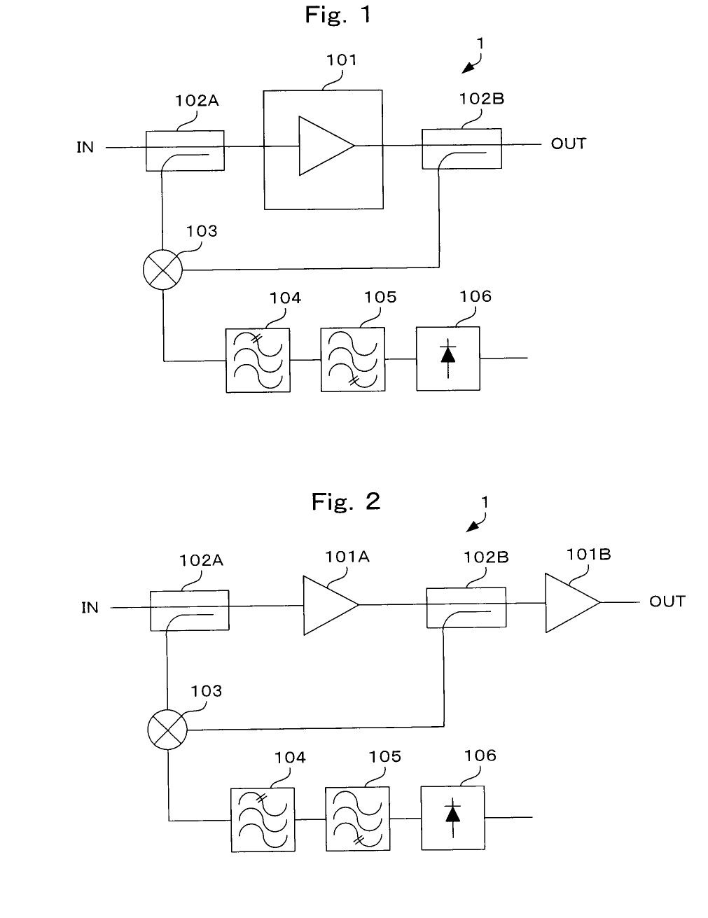

FIG. 1 is a diagram illustrating a structure of the amplifier 1 according to the present embodiment. As illustrated in FIG. 1, the amplifier 1 comprises a power amplifier 101 for amplifying an unmodulated high-frequency input signal IN, a first directional coupler 102A as the first branching device which is provided at an input terminal side of the power amplifier 101 and extracts a signal, a second directional coupler 102B as the second branching device which is provided at an output terminal side of the power amplifier 101 and extracts a signal, a mixer for mixing a signal from the first directional coupler 102A and a signal from the second directional coupler 102B, a low-pass filter 104 for removing a frequency band component of the input signal IN from an output signal of the mixer 103, a high-pass filter 105 for removing a DC component from an output signal of the low-pass filter 104, and a wave detector 106 for extracting a signal.

The power amplifier 101 may be a multi-stage amplifier comprising a plurality of amplification devices.

The first branching device and the second branching device are not limited to a directional coupler. When a directional coupler is used for the first branching device and the second branching device, the directional coupler 102A and the second directional coupler 102B may use a well-known directional coupler.

The operations of the amplifier according to the present embodiment will be described below.

At first, when an abnormal oscillation does not occur, a voltage amplitude of an output signal of the first directional coupler 102A is expressed in Equation (1).

a₁=A₁ sin(ω₁t+φ₁) (1)

A voltage amplitude of an output signal of the second directional coupler 102B is expressed in Equation (2).

a₂=A₂₁ sin(ω₁t+φ₂₁) (2)

where A indicates a constant, ω indicates an input signal, t indicates a time and φ indicates an amplitude.

Therefore, when the mixer 103 is an ideal mixer, an output of the mixer 103 is expressed in Equation (3).

$${a}_{1} {a}_{2} = \frac{{A}_{1} {A}_{21}}{2} \{ cos ( {φ}_{1} - {φ}_{21} ) - cos ( 2 {ω}_{1} t + {φ}_{1} + {φ}_{21} ) \} \qquad ( 3 )$$

A leak of an input signal to the output occurs in the actual mixer 103, but a frequency component of a second harmonic and a frequency component of an input signal IN are removed in the low-pass filter 104 so that the output of the low-pass filter 104 has only the DC term in Equation (3).

Therefore, the output of the high-pass filter 105 is 0 and the output of the wave detector 106 is also 0.

On the other hand, when an abnormal oscillation occurs, a voltage amplitude of an output signal of the first directional coupler 102A has at least one frequency component of other than the input signal as expressed in Equation (4).

a₂′=A₂₁ sin(ω₁t+φ₂₁)+A₂₂ sin(ω₂t+φ₂₂)) (4)

Therefore, the output of the mixer 103 is expressed in Equation (5).

$${a}_{1} {a}_{2}^{′} = \frac{{A}_{1} {A}_{21}}{2} \{ cos ( {φ}_{1} - {φ}_{21} ) - cos ( 2 {ω}_{1} t + {φ}_{1} + {φ}_{21} ) \} + \frac{{A}_{1} {A}_{22}}{2} [ cos \{ ( {ω}_{1} - {ω}_{2} ) t + {φ}_{1} - {φ}_{22} \} - cos \{ ( {ω}_{1} + {ω}_{2} ) t + {φ}_{1} + {φ}_{22} \} ] \qquad ( 5 )$$

When an abnormal oscillation occurs, the following terms are obtained, which are the outputs of a difference between and a sum of the frequency of other than the input signal and the frequency of the input signal.

$$\frac{{A}_{1} {A}_{22}}{2} [ cos \{ ( {ω}_{1} - {ω}_{2} ) t + {φ}_{1} - {φ}_{22} \} - cos \{ ( {ω}_{1} + {ω}_{2} ) t + {φ}_{1} + {φ}_{22} \} ]$$

The difference and sum are not removed by the low-pass filter 104 and the high-pass filter 105, and are detected by the wave detector 106.

Therefore, an abnormal oscillation occurring near the frequency band of the input signal can be detected.

FIG. 2 is a diagram illustrating a structure of a variant of the amplifier 1 according to the present embodiment. As illustrated in FIG. 2, the amplifier 1 comprises a first power amplifier 101A for amplifying an unmodulated high-frequency input signal IN, the first directional coupler 102A as the first branching device which is provided at an input terminal side of the first power amplifier 101A and extracts a signal, a second power amplifier 101B which is cascaded to the first power amplifier 101A and amplifies an output signal of the first power amplifier 101A, the second directional coupler 102B as the second branching device which is provided between an output terminal side of the first power amplifier 101A and an input terminal side of the second power amplifier 101B and extracts a signal, the mixer 103 for mixing a signal from the first directional coupler 102A and a signal from the second directional coupler 102B, the low-pass filter 104 for removing a frequency band component of the input signal IN from an output signal of the mixer 103, the high-pass filter 105 for removing a DC component from an output signal of the low-pass filter 104, and the wave detector 106 for extracting a signal.

The power amplifier 101 may be a multi-stage amplifier comprising a plurality of amplification devices.

The first branching device and the second branching device are not limited to a directional coupler. When a directional coupler is used for the first branching device and the second branching device, the directional coupler 102A and the second directional coupler 102B may use a well-known directional coupler.

The second directional coupler 102B outputs an abnormal oscillation occurring between the first power amplifier 101A and the second amplifier 101B together with the input signal.

Therefore, the output of the second directional coupler is equal to that in Equation (3).

A component of the abnormal oscillation is extracted by the wave detector 106 through the above operations.

As described above, the amplifier 1 comprises the power amplifier 101 for amplifying an unmodulated high-frequency input signal IN, the first directional coupler 102A as the first branching device which is provided at the input terminal side of the power amplifier 101 and extracts a signal, the second directional coupler 102B as the second branching device which is provided at the output terminal side of the power amplifier 101 and extracts a frequency component of an abnormal oscillation together with a frequency component of the input signal, the mixer 103 for mixing a signal from the first directional coupler 102A and a signal from the second directional coupler 102B, the low-pass filter 104 for removing a frequency band component of the input signal IN from an output signal of the mixer 103, the high-pass filter 105 for removing a DC component from an output signal of the low-pass filter 104, and the wave detector 106 for extracting a signal.

While certain embodiments have been described, these embodiments have been presented by way of example only, and are not intended to limit the scope of the inventions. Indeed, the novel methods and apparatuses described herein may be embodied in a variety of other forms; furthermore, various omissions, substitutions and changes in the form of the methods and systems described herein may be made without departing from the spirit of the inventions. The accompanying claims and their equivalents are indeed to cover such forms or modifications as would fall within the scope and spirit of the inventions.

What is claimed is:

1. An amplifier comprising:
a power amplifier configured to amplify an unmodulated high-frequency input signal;
a first branching device which is provided at an input terminal side of the power amplifier and extracts a signal;
a second branching device which is provided at an output terminal side of the power amplifier and extracts a signal;
a mixer configured to mix a signal from the first branching device and a signal from the second branching device;
a low-pass filter configured to remove a frequency band component of the input signal from an output signal of the mixer;
a high-pass filter configured to remove a DC component from an output signal of the low-pass filter; and
a wave detector configured to extract a signal.

2. The amplifier according to claim 1, wherein
the power amplifier is a multi-stage amplifier comprising a plurality of amplification devices.

3. The amplifier according to claim 2, wherein
the branching device is a directional coupler.

4. An amplifier comprising:
a first power amplifier configured to amplify an unmodulated high-frequency input signal;
a first branching device which is provided at an input terminal side of the first power amplifier and extracts a signal;
a second power amplifier which is cascaded to the first power amplifier and amplifies an output signal of the first power amplifier;
a second branching device which is provided between an output terminal side of the first power amplifier and an input terminal side of the second power amplifier and extracts a signal;
a mixer configured to mix a signal from the first branching device and a signal from the second branching device;
a low-pass filter configured to remove a frequency band component of the input signal from an output signal of the mixer;
a high-pass filter configured to remove a DC component from an output signal of the low-pass filter; and
a wave detector configured to extract a signal.

5. The amplifier according to claim 4, wherein
the branching device is a directional coupler.
